(19) United States
(12) Patent Application Publication
(10) Pub. No.: US 2008/0030240 A1
(43) Pub. Date: Feb. 7, 2008

(54) LOW SYSTEMATIC OFFSET, TEMPERATURE INDEPENDENT VOLTAGE BUFFERING

(76) Inventor: Eric Scheuerlein, Los Gatos, CA (US)

Correspondence Address: WAGNER, MURABITO & HAO LLP, Third Floor, Two North Market Street, San Jose, CA, 95113, US

(21) Appl. No.: 11/462,620

(22) Filed: Aug. 4, 2006

(51) Int. Cl. H03B 1/00

(52) U.S. Cl. 327/108

(57) ABSTRACT

A voltage buffer circuit is comprised of a differential input stage, a bias current generator, a first current mirror, and a second current mirror. The differential input stage has a non-inverting input coupled with an input voltage, and the input voltage is buffered to an output of the input stage as an output voltage. The bias current generator is coupled with the input voltage. The input voltage controls generation of a bias current in the bias current generator. The first current mirror is coupled with the differential input stage, and sets a mirror voltage of the input stage. The second current mirror is coupled with the bias current generator and to the differential input stage, and mirrors the bias current to create a tail current for the differential input stage.

### TECHNICAL FIELD

Embodiments of the present technology pertain to analog circuit design, and more particularly to voltage buffers.

### BACKGROUND ART

The desired operation of a voltage buffer is that a voltage that is received on the input is accurately reproduced on the output. FIG. 1 shows a typical voltage buffer 100 that is comprised of an input stage 105 and a current mirror 110. Input stage 105 is comprised of two transistors 102 and 103, and has an inverting input on the gate of transistor 103 and a non-inverting input on the gate of transistor 102. A tail current is comprised of the combined currents which flow through the two branches of input stage 105. A voltage to be buffered (V_{BUFF}) is received on the non-inverting input and is buffered to the output of voltage buffer 100. The output is coupled with the inverting input to provide negative feedback. Current mirror 110 is comprised of two transistors 111 and 112 which are gate connected, additionally, transistor 111 is diode connected with its gate coupled with its drain.

In such a voltage buffer circuit, it is desirable that any difference between the non-inverting and the inverting input has a great effect on the output. The expression for such a buffer is represented by Equation 1 in Table 1, where “A” is the gain of the buffer. When “A” is a very large value, such as with unity gain negative feedback, the result is shown by Equation 2 of Table 1. In such a case, where “A” is a very large value, and the inverting input voltage and non-inverting input voltage are equal, the operation of the voltage buffer is roughly represented by Equation 3 of Table 1. In other words, when “A” is large, the output voltage of voltage buffer 100 should be more or less equal to the input voltage of voltage buffer 100.

TABLE 1
Exemplary Voltage Buffer Equations

Equation 1: V_{OUT} = A(V⁺ − V⁻)
$\text{Equation 2:} \frac{{V}_{OUT}}{A} = 0$
Equation 3: V⁺ = V_{OUT}
$\text{Equation 4:} \frac{1}{2} = {I}_{TAIL} = μn \cdot {A ( {V}_{IN +} - {V}_{SOURCE} - {V}_{thn1} )}^{2}$
Equation 5: (V_{IN+} − V_{SOURCED} − Vₜₕₙ₁)² = (V_{OUT} − V_{SOURCE} − Vₜₕₙ₂)²

With respect to voltage buffer 100, transistors 102 and 103 have their sources connected, so their sources are at the same voltage. Because the sources are at the same voltage, the gate voltages of transistors 102 and 103 have to be equal as well. Devices 111 and 112 function as a current mirror and ensure that equivalent currents are flowing through transistors 111 and 112. Likewise, when the output has settled to the buffered voltage and is not pulling any current this current mirror also ensures that the currents flowing through transistors 102 and 103 are equal.

Typically, some external source such as a voltage proportional to absolute temperature or a random voltage from some other part of a larger circuit is used to generate the tail current. When the tail current is constant, and device 102 and 103 are in saturation, the current through transistor 102 is represented by Equation 4 of Table 1, where μn represents the mobility of electrons in the channel of an n-type metal oxide semiconductor (NMOS) and Vthn represents the threshold voltage of a NMOS. Equation 5 of Table 1, indicates that when Vth1 and Vth2 differ between the two parallel branches of voltage buffer 100, a mismatch error related offset error will result which will prevent the buffered voltage from exactly equaling the output voltage of voltage buffer 100.

However, this mismatch related offset error can be removed by dynamic element matching (or chopping).

Additionally, it can be seen that V_{OUT} will generally be constant and similar to the voltage being buffered (this is the function of a voltage buffer). However, V_{MIRROR} will be dependent upon the gate source voltage that device 111 requires in order to source the current that is being supplied by I_{TAIL}. In voltage buffer circuits in present use, this will cause V_{MIRROR} to change with temperature or other variations related to the bias current used to generate the tail current. Since V_{OUT} typically remains constant while V_{MIRROR} changes, devices 102 and 103 will have different drain source voltages. This difference in drain source voltages on input devices 102 and 103 cause a systematic offset error associated with channel length modulation. The systematic offset error varies, for example, with temperature and cannot be removed by dynamic element matching.

As ever smaller processes are used to create electronic devices, such systematic offset errors due to channel length modulation become a larger concern in voltage buffer circuits. Cascoding is often used to somewhat limit the effect of a changing V_{MIRROR} upon input devices 102 and 103. Limiting the effect of systematic offset may be useful sometimes, but it is more desirable to eliminate systematic offset error. This is especially true when a very accurate voltage buffer is needed.

### SUMMARY

A voltage buffer circuit is comprised of a differential input stage, a bias current generator, a first current mirror, and a second current mirror. The differential input stage has a non-inverting input coupled with an input voltage, and the input voltage is buffered to an output of the input stage as an output voltage. The bias current generator is coupled with the input voltage. The input voltage controls generation of a bias current in the bias current generator. The first current mirror is coupled with the differential input stage, and sets a mirror voltage of the input stage. The second current mirror is coupled with the bias current generator and to the differential input stage, and mirrors the bias current to create a tail current for the differential input stage.

### BRIEF DESCRIPTION OF THE DRAWINGS

The accompanying drawings, which are incorporated in and form a part of this specification, illustrate embodiments of the presented technology of low systematic offset, temperature independent voltage buffering and, together with the description, serve to explain the principles of the technology:

FIG. 1 is a schematic of a differential input single ended output amplifier used as a voltage buffer.

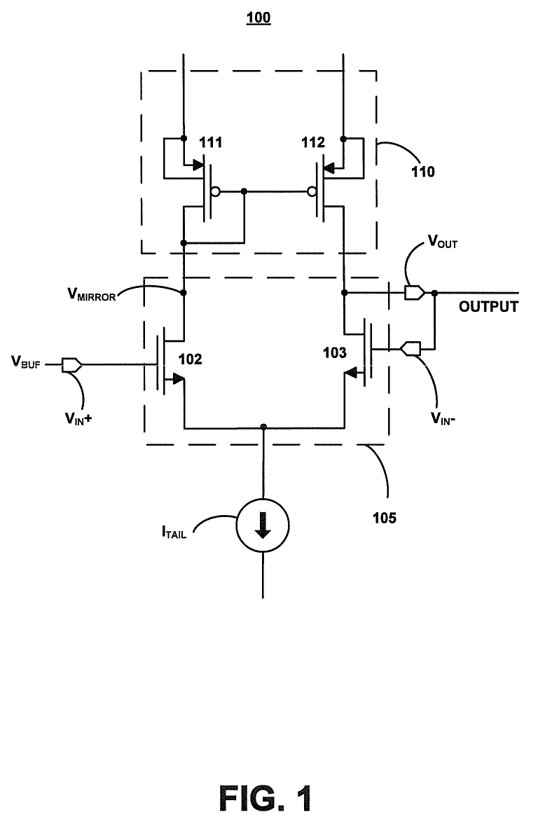

FIG. 2 is a schematic of a low systematic offset, temperature independent voltage buffer, according to an embodiment of the present technology.

FIG. 3 is a flow diagram of a method for buffering a voltage, according to an embodiment of the present technology.

The drawings referred to in this description should not be understood as being drawn to scale unless specifically noted.

### DETAILED DESCRIPTION

Reference will now be made in detail to embodiments of the present technology of low systematic offset, temperature independent voltage buffering, examples of which are illustrated in the accompanying drawings. While the present technology will be described in conjunction with the preferred embodiments, it will be understood that they are not intended to limit the described technology to these embodiments. On the contrary, the present technology is intended to cover alternatives, modifications, and equivalent, which may be included within the spirit and scope of the technology as defined by the appended claims. Furthermore, in the following detailed description of the present technology, numerous specific details are set forth in order to provide a thorough understanding of the present technology. However, it will be recognized by one skilled in the art that the present technology may be practiced without these specific details or with equivalents thereof. In other instances, well-known methods, procedures, components, and circuits have not been described in detail as not to unnecessarily obscure aspects of the present technology.

### Overview of Discussion

The present technology for low systematic offset, temperature independent voltage buffering provides a circuit and methodology and circuit architecture usable to ensure low systematic offset in a differential buffer. The voltage buffering circuit generates a bias current from the voltage that it is buffering. The bias current is such that an active current mirror node and an output node remain at the same voltage, thus causing the input devices of the differential buffer to see correspondingly equivalent voltages on all of their terminals. This causes the input devices to experience channel length modulation error which is substantially equal. As such systematic offset error is minimized and does not vary with temperature.

With respect to this Detailed Description, an exemplary embodiment of a low systematic offset, temperature independent voltage buffer circuit will be described. The discussion will start with an overview of this circuit and then move on to describe the structure and operation of blocks and components of this circuit. An exemplary method for buffering a voltage in accordance with the present technology will then be described, and will be facilitated by the discussion of the operation of the exemplary low systematic offset, temperature independent voltage buffer circuit.

### Exemplary Low Systematic Offset, Temperature Independent Voltage Buffer

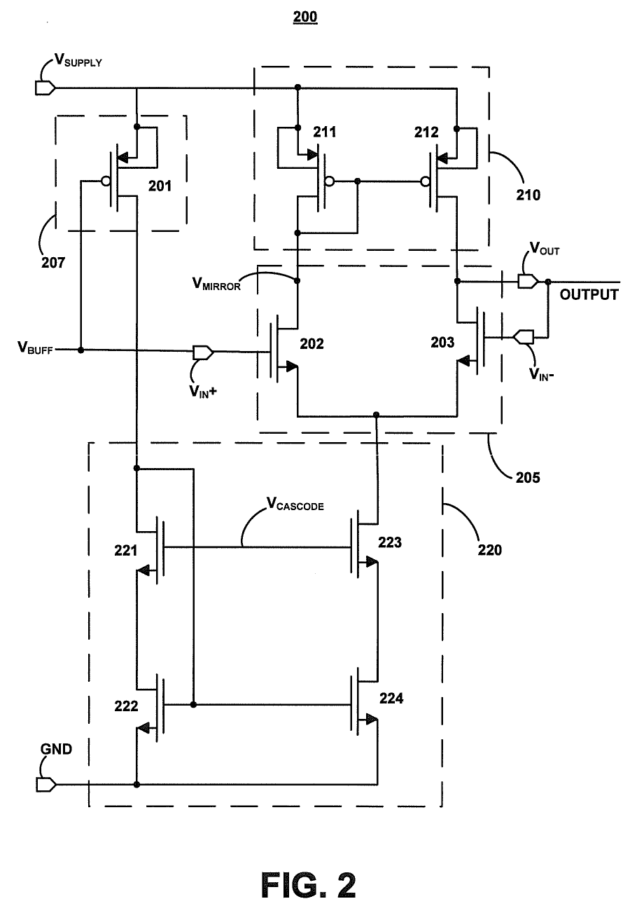

FIG. 2 shows a schematic of a low systematic offset, temperature independent voltage buffer 200, according to an embodiment of the present technology. Voltage buffer 200 is comprised of: a bias current generator 207; a differential input stage 205; a first current mirror 210; and a second current mirror 220.

Differential input stage 205 is configured with a non-inverting input (Vᵢₙ⁺) coupled with an input voltage (V_{BUFF}). The input voltage is buffered to the output of buffer 200, where it appears as an output voltage. Differential input stage 205 is comprised of two transistors, 202 and 203. In FIG. 2, transistors 202 and 203 are shown as n-type metal oxide semiconductor field effect transistors (MOSFETs). However it is appreciated that in a complementary metal oxide semiconductor (CMOS) process, the supply and ground potentials can be reversed, and the n-type MOSFETs 202 and 203 can be replaced by p-type MOSFETs. The sources of transistors 202 and 203 are coupled together to ensure that they see the same voltage potential. The gate of transistor 202 provides the non-inverting input of buffer 200. The output of buffer 200 (V_{OUT}) is taken from the drain of transistor 203. The gate of transistor 203 provides the inverting input (Vᵢₙ⁻) of differential input stage 205. The gate of transistor 203 is coupled to its drain, such that the inverting input of differential input stage 205 is coupled to the output of buffer 200 in a unity gain, negative feedback configuration. This configuration along with the action of current mirror 210 sets up a condition where the drain of transistor 203 and the gates of transistors 202 and 203 should see equivalent voltages that are equal to the voltage of the input voltage V_{BUFF}. Additionally, as will be seen, the configuration of buffer circuit 200 also ensures that the drain voltage (V_{MIRROR}) of transistor 202 is an equivalent voltage to the drain voltage (V_{OUT}) of transistor 203.

Current mirror 210 is coupled with the supply voltage (V_{SUPPLY}) and to differential input stage 205. Current mirror 210 sets the branch currents equal in differential input stage 205 while biasing the drain node of input device 202. Thus, current mirror 210 sets voltage (V_{MIRROR}) on the drain of transistor 202 in differential input stage 205. As shown in FIG. 2, current mirror 210 is comprised of two transistors 211 and 212. In FIG. 2, transistors 211 and 212 are shown as p-type MOSFETs. However it is appreciated that in a CMOS process, the supply and ground potentials can be reversed, and the p-type MOSFETs 211 and 212 can be replaced by n-type MOSFETs. In FIG. 2, the sources of transistors 211 and 212 are coupled with the supply voltage and are therefore also coupled with the source of transistor 201. The gates of transistors 211 and 212 are coupled with one another, and additionally the gate of transistor 211 is coupled with the drain of transistor 211 in a diode connection configuration. The drain of transistor 211 is coupled with the drain of transistor 202, while the drain of transistor 212 is coupled with the drain of transistor 203. Current mirror 210 functions to ensure that each branch of buffer 200 sees an equivalent current, i.e., current mirror 210 ensures that the equivalent currents flow through input transistors 202 and 203.

Bias current generator 207 is coupled with a supply voltage and to the input voltage (V_{BUFF}). The input voltage is used by bias current generator 207 to control generation of a bias current which is used to create a tail current for voltage buffer 200. As shown in FIG. 2, bias current generator is comprised of a single transistor 201. In FIG. 2, transistor 201 is shown as a p-type MOSFET. However it is appreciated that in a CMOS process, the supply and ground potentials can be reversed, and the p-type MOSFET 201 can be replaced by an n-type MOSFET. The source of transistor 201 is coupled with the supply voltage and to current mirror 210. The drain of transistor 201 is coupled with current mirror 220. The gate of transistor 201 is coupled with the input voltage (V_{BUFF}). In this manner, transistor 201 generates a bias current under the control of the input voltage. Thus fluctuations in the input voltage due to temperature changes or other reasons will cause proportional fluctuations in the bias current generated by transistor 201. The drain of transistor 201 is coupled with current mirror 220, this allows the bias current generated in transistor 201 to be mirrored to form the tail current coupled with the source junction of transistors 202 and 203 of differential input stage 205.

Current mirror 220 is coupled with bias current generator 207 and to differential input stage 205. Current mirror 220 mirrors the bias current generated by bias current generator 207 to create a tail current for differential input stage 205. Current mirror 220 is configured in low voltage cascode configuration which is well known in the art. As shown in FIG. 2, current mirror 220 is comprised of four transistors: 221, 222, 223, and 224 which are in a cascoded arrangement. In FIG. 2, transistors 221, 222, 223, and 224 are shown as n-type MOSFETs. However, it is appreciated that in a CMOS process, the supply and ground potentials can be reversed, and the n-type MOSFETs 221, 222, 223, and 224 can be replaced by p-type MOSFETs. Transistor 221 receives the bias current from bias current generator 207. As shown, the drain of transistor 221 is coupled with the drain of transistor 201 and also to the gate of transistors 222 and 224. The source of transistor 221 is coupled with the drain of transistor 222. The gate of transistor 221 is coupled with the gate of transistor 223 and both gates are biased with a bias voltage (V_{CASCODE}). The sources of transistors 222 and 224 are coupled with ground. The source of transistor 223 is coupled with the drain of transistor 224. Finally, the drain of transistor 224 is coupled with the common source junction of transistors 202 and 203.

In current mirror 220, transistors 221 and 222 provide a path to ground for bias current generator 207, while transistors 223 and 224 provide a path to ground for differential input stage 205 and current mirror 210. Additionally, it should be noted that in the present embodiment, transistors 223 and 224 are twice the size of transistors 221 and 222. This allows current mirror 220 to create a tail current that is twice the size of the bias current supplied as an input. It is appreciated that in other configurations, more or less transistors may be used in current mirror 220, and that transistors may be of different sizes depending on the size of the bias current received by current mirror 220 and the desired size of the tail current which current mirror 220 supplies. In the displayed embodiment of FIG. 2, doubling the bias current creates a tail current, which is split equally between input devices 202 and 203 (due to current mirror 210 causing each input device to have an equivalent current). Thus current mirror 220 supplies each input transistor (202 and 203) with a component of the tail current (namely one half of the tail current) which is equal to the bias current generated by bias current generator 207. Similarly, each branch of current mirror 210 also sees a current equivalent to the bias current. It is important to note that this tail current varies up and down in proportion to changes in the bias current.

By providing a tail current that results in branch currents in current mirror 210 and differential input stage 205 that are equivalent to the bias current, device 211 is forced to supply a mirror voltage that is equivalent to the input voltage (V_{BUFF}). This is because transistors 201 and 211 see the same source voltage and are sourcing the same current. By definition then, when these devices are in saturation, they will also have equivalent gate voltages, which are equal to the input voltage (V_{BUFF}). Since the drain and gate of transistor 211 are coupled, the voltage (V_{MIRROR}) on the drain of transistor 211 will also be equivalent to (V_{BUFF}). As the input voltage (V_{BUFF}) fluctuates, for instance with temperature, V_{MIRROR} will track it in synchronization since the current in device 211 will fluctuate in synchronization with and be equivalent to the bias current generated under control of the input voltage. Thus, the particular tail current supplied by current mirror 220 causes V_{MIRROR}, to be an equivalent voltage to the input voltage and output voltage of voltage buffer 220.

By supplying a tail current that sets circuit conditions which assure that V_{MIRROR} is equivalent to both the input voltage and output voltage of differential input stage 205, conditions on the sources, gates, and drains of input devices 202 and 203 will always see correspondingly equivalent voltages in addition to the equivalent currents that run through each input device (202 and 203). As a consequence, the drain to source voltages of input devices 202 and 203 will always be equal or substantially equal. This ensures a minimization of systematic offset error of voltage buffer 200 by minimizing differences in channel length modulation between input transistors 202 and 203. When the channel length modulation errors are substantially equivalent or exactly equivalent, related offset error will be minimized or completely eliminated. Additionally, the tail current supplied to differential input stage 205 varies in synchronization with temperature variations in the input voltage, rather than in proportion to temperature or in some other way that differs from the variations of the input voltage. This ensures that the minimized systematic offset error related to channel length modulation is temperature invariant, by causing the substantially equivalent channel length modulation errors of input devices 202 and 203 to vary in synchronization with one another.

### Exemplary Method for Buffering a Voltage

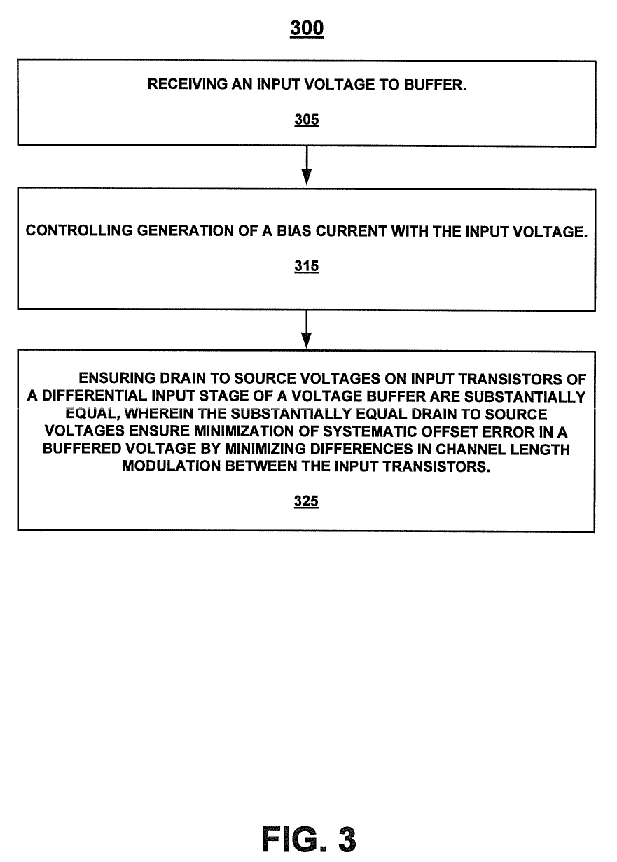

The following discussion sets forth in detail the operation of an exemplary method of the present technology for low systematic offset, temperature independent voltage buffering. With reference to FIG. 3, flow diagram 300 illustrates exemplary steps used by an embodiment of the present technology. Although specific steps are disclosed in flow diagram 300, such steps are exemplary. That is, embodiments are well suited to performing various other steps or variations of the steps recited in flow diagram 300. It is appreciated that the steps in flow diagram 300 may be performed in an order different than presented and that not all of the steps may be performed.

FIG. 3 is a flow diagram 300 of a method for buffering a voltage, according to an embodiment of the present technology. Flow diagram 300 is described in conjunction with references to exemplary voltage buffer circuit 200 of FIG. 2. In the exemplary embodiment of FIG. 2, transistors 202, 203, 221, 222, 223 and 224 are shown as n-type MOSFETs and transistors 201, 211 and 212 are shown as p-type MOSFETs. However it is appreciated that in a CMOS process, the supply and ground potentials can be reversed and the n-type MOSFETs (202, 203, 221, 222, 223, and 224) can be replaced by p-type MOSFETs while the p-type MOSFETs (201, 211, and 212) are replaced by n-type MOSFETs.

In 305 of flow diagram 300, in one embodiment, a voltage buffer receives an input voltage to buffer. For example, in one embodiment illustrated in FIG. 2, this comprises receiving the input voltage on gate of input transistor 202 of differential input stage 205, and simultaneously receiving the input voltage at current generator 207 that is used for generating a bias current which is used to create a tail current for differential input stage 205. For instance, as shown in FIG. 2, current generator 207 utilizes the input voltage as a gate voltage on transistor 201.

In 315 of flow diagram 300, in one embodiment, generation of a bias current is controlled with the input voltage. For example, in FIG. 2, transistor 201, a MOSFET, functions as a current generator to generate the bias current. This bias current varies in proportion to the input voltage which is coupled with the gate of transistor 201.

In 325 of flow diagram 300, in one embodiment, drain to source voltages on input transistors of a differential input stage are ensured to be substantially equal. The substantially equal drain to source voltages ensure minimization of systematic offset error by minimizing differences in channel length modulation between the input transistors. As shown, and previously described, in conjunction with FIG. 2, in one such embodiment, current mirror 220 receives a bias current from bias current generator 207, mirrors it, and supplies the mirrored current as a tail current to differential input stage 205. For example, in FIG. 2, tail current is supplied at the junction of the source nodes of input transistors 202 and 203. Additionally, as shown in the embodiment of FIG. 2, current mirror 220 multiplies the bias current during the mirroring such that each input transistor (202 and 203) of differential input stage 205 receives a component of the tail current which is equal to the bias current.

As shown in the embodiment of FIG. 2, this tail current creates circuit conditions which ensure that voltages on the sources of transistors 202 and 203 will be equivalent, voltages on the drains of transistors 202 and 203 will be equivalent, and voltages on the gates of transistors 202 and 203 will be equivalent. Additionally, in the exemplary embodiment of FIG. 2, the currents through transistors 202 and 203 will be equivalent to one another and to the bias current. This ensures that the drain to source voltage on input transistor 202 will be substantially equivalent (or equal) to the drain to source voltage on transistor 203. When the drain to source voltages on input devices 202 and 203 are substantially equivalent, the channel length modulation error on transistor 202 will also be substantially equivalent to the channel length modulation error on transistor 203. In such conditions, offset error due to channel length modulation error differences will be minimized (or eliminated if the channel length modulation errors are exactly equal).

Moreover, the tail current is set with the bias current such that a mirror voltage supplied to the differential input stage is always equal to the input voltage. This is the same input voltage which is received at the input of the voltage buffer and is also used to create the tail current. This advantageously causes the mirror voltage to fluctuate up and down in synchronization with both the input and output voltages of the voltage buffer. Similarly, the mirror voltage experiences the same temperature fluctuations as the input voltage. A process for setting such a tail current was previously shown and described in conjunction with the embodiment of FIG. 2. In the exemplary embodiment shown in FIG. 2, an advantage that results from this is that the gate source voltages of input devices 202 and 203 will be substantially equivalent across temperature, thus ensuring that the systematic offset error related to channel length modulation is temperature invariant.

Embodiments of the present technology for low systematic offset, temperature independent voltage buffering are thus described. While the present technology has been described in particular embodiments, it should be appreciated that the present technology should not be construed as limited by such embodiments, but rather construed according to the below claims.

What is claimed is:

1. A voltage buffer circuit, said circuit comprising:
a differential input stage having a non-inverting input coupled with an input voltage, wherein said input voltage is buffered to an output of said input stage as an output voltage;
a bias current generator coupled with said input voltage, wherein said input voltage controls generation of a bias current in said bias current generator;
a first current mirror coupled with said differential input stage, wherein said first current mirror sets a mirror voltage of said differential input stage; and
a second current mirror coupled with said bias current generator and to said differential input stage, wherein said second current mirror mirrors said bias current to create a tail current for said differential input stage.

2. The circuit of claim 1, wherein said output voltage of said differential input stage is an equivalent voltage to said mirror voltage.

3. The circuit of claim 1, wherein said differential input stage comprises:
a first input transistor, wherein a gate of said first input transistor comprises said non-inverting input; and
a second input transistor, wherein a gate of said second input transistor comprises an inverting input, and wherein said inverting input is coupled with said output of said input stage in a unity gain negative feedback configuration.

4. The circuit of claim 1, wherein said first input transistor and said second input transistor comprise metal oxide semiconductor field effect transistors.

5. The circuit of claim 1, wherein said bias current generator comprises a transistor, and wherein said input voltage controls said bias current generated by said transistor.

6. The circuit of claim 5, wherein said transistor comprises a metal oxide semiconductor field effect transistor (MOSFET), and wherein a gate of said MOSFET is coupled with said input voltage.

7. The circuit of claim 1, wherein said second current mirror multiplies said bias current such that each input transistor of said differential input stage receives a component of said tail current which is equal to said bias current.

8. The circuit of claim 1, wherein said tail current ensures that drain to source voltages of input transistors of said differential input stage are substantially equal, wherein said substantially equal drain to source voltages ensure minimization of a systematic offset error of said voltage buffer by minimizing differences in channel length modulation between said input transistors.

9. The circuit of claim 8, wherein said tail current varies in proportion to variations of said input voltage, ensuring said minimized systematic offset error is temperature invariant.

10. An apparatus for ensuring low systematic offset and temperature independence of a voltage buffer, said apparatus comprising:
a bias current generator coupled with an input voltage, wherein said input voltage is also received by a differential input stage of said voltage buffer, and wherein said bias current generator generates a bias current that varies in proportion to variations in said input voltage;
a current mirror coupled with said bias current generator, wherein said current mirror mirrors said bias current to supply a tail current for said differential input stage; and
wherein said tail current causes drain to source voltages on input transistors of said differential input stage to be substantially equal, ensuring a minimized systematic offset error by minimizing differences in channel length modulation between said input transistors.

11. The circuit of claim 10, wherein said bias current generator comprises a transistor, and wherein said input voltage controls said bias current generated by said transistor.

12. The circuit of claim 11, wherein said transistor comprises a complementary metal oxide semiconductor field effect transistor (MOSFET), and wherein a gate of said complementary MOSFET is coupled with said input voltage, and a drain of said complementary MOSFET transistor is coupled with said current mirror.

13. The circuit of claim 10, wherein said current mirror multiplies said bias current such that each said input transistor receives a component of said tail current which is equal to said bias current.

14. The circuit of claim 13, wherein said current mirror varies said tail current in proportion to variations in said bias current, ensuring temperature invariance of said systematic offset by forcing said drain to source voltages of said input transistors to vary in synchronization with said input voltage and in synchronization with each another.

15. A method for buffering a voltage, said method comprising:
receiving an input voltage to buffer;
controlling generation of a bias current with said input voltage; and
ensuring drain to source voltages on input transistors of a differential input stage of a voltage buffer are substantially equal, wherein said substantially equal drain to source voltages ensure minimization of systematic offset error in a buffered voltage by minimizing differences in channel length modulation between said input transistors.

16. The method as recited in claim 15, wherein said receiving an input voltage to buffer comprises:
receiving said input voltage on a gate of one of said input transistors; and
receiving said input voltage at a current generator used for generating said bias current.

17. The method as recited in claim 15, wherein said controlling generation of a bias current with said input voltage comprises:
utilizing said input voltage as a gate voltage of a transistor, wherein said transistor functions as a current generator to generate said bias current.

18. The method as recited in claim 15, wherein said ensuring drain to source voltages on input transistors of a differential input stage of a voltage buffer are substantially equal comprises:
mirroring said bias current to supply a tail current to said differential input stage.

19. The method as recited in claim 18, wherein said mirroring said bias current to supply a tail current to said differential input stage further comprises:
multiplying said bias current such that each input transistor receives a component of said tail current which is equal to said bias current.

20. The method as recited in claim 15, wherein said ensuring drain to source voltages on input transistors of a differential input stage of a voltage buffer are substantially equal comprises:
setting said tail current with said bias current such that a mirror voltage within said differential input stage is equal to said input voltage.
